(19) United States
(12) Patent Application Publication
(10) Pub. No.: US 2016/0141268 A1
(43) Pub. Date: May 19, 2016

(54) METHOD FOR MANUFACTURING SEMICONDUCTOR APPARATUS AND SEMICONDUCTOR APPARATUS

(71) Applicant: SHIN-ETSU CHEMICAL CO., LTD., Tokyo (JP)

(72) Inventors: Tomoaki NAKAMURA, Annaka (JP); Hideki AKIBA, Annaka (JP); Toshio SHIOBARA, Annaka (JP)

(21) Appl. No.: 14/922,826

(22) Filed: Oct. 26, 2015

(30) Foreign Application Priority Data
Nov. 19, 2014 (JP) 2014-234396

(51) Int. Cl. H01L 23/00; H01L 21/56; H01L 21/78

(52) U.S. Cl. CPC H01L 24/96; H01L 21/78; H01L 21/561; H01L 21/563; H01L 2924/3511

(57) ABSTRACT

A method for manufacturing a semiconductor-apparatus, including an encapsulating step of a device mounting surface of a substrate having semiconductor-devices mounted thereon with a base-attached encapsulant having a base and a thermosetting resin layer formed on one surface of the base, the semiconductor-devices being mounted by flip-chip bonding, the encapsulating step including a unifying stage of the substrate having the semiconductor-devices mounted thereon and the base-attached encapsulant under a reduced pressure condition with a vacuum of 10 kPa or less and a pressing stage of the unified substrate with a pressure of 0.2 MPa or more. A method for manufacturing a semiconductor-apparatus that can inhibit warping even when a thin substrate with a large area is encapsulated, sufficiently perform underfilling of semiconductor-devices mounted by flip-chip bonding, and provide a semiconductor-apparatus excellent in encapsulating performance such as heat and moisture resistance reliabilities without void and non-filling portion of the encapsulating layer.

### BACKGROUND OF THE INVENTION

1. Field of the Invention

The present invention relates to a method for manufacturing a semiconductor apparatus using a base-attached encapsulant and to a semiconductor apparatus manufactured by the method.

2. Description of the Related Art

In recent years, semiconductor apparatuses have been more integrated and thinned as electronic devices are reduced in size and weight and improved in performance. There has been a transition of semiconductor apparatuses to area mounting semiconductor apparatuses, represented by ball grid arrays (BGA). These semiconductor apparatuses tend to be manufactured by collectively molding a thin substrate with a large area from the viewpoint of productivity. The problem of the warp of substrates after molding however has been revealed.

The semiconductor mounting technique has also been shifted from pin insertion to surface mounting; currently bare chip mounting is becoming more prevalent. Flip chip mounting is one of the bare chip mounting techniques. In flip chip mounting, electrode terminals called bumps are formed on a semiconductor device. This can be directly mounted on a motherboard, but is in many cases fixed on a printed circuit board (such as an interposer) to form a package and mounted on a motherboard via external connection terminals (also referred to as outer balls or outer bumps) provided on the package. The bumps on a semiconductor device to be connected with the interposer are called inner bumps, which are electrically connected with a large number of fine interfaces (referred to as pads) on the interposer. Since junctions between the inner bumps and the pads are very small and thus mechanically weak, the junctions are encapsulated and reinforced with resin. The conventional procedure most often used for encapsulating a semiconductor apparatus after flip chip bonding involves previous fusion bonding between the inner bumps and the pads, underfilling (also referred to as capillary flow) by injecting a liquid reinforcement in a gap between the semiconductor apparatus and the interposer, and compression molding under heating with a liquid epoxy resin or an epoxy molding compound, etc., to overmold semiconductor devices.

However, this procedure has some problems: voids are produced in the encapsulating resin reinforcement; encapsulation and reinforcement requires much effort; since the underfilling resin is different from the resin for encapsulating semiconductor devices, a stress is applied to a resin interface, causing reduction in reliability.

For resolving these problems, there have been developed transfer mold underfill and compression mold underfill to perform overmolding and underfilling at the same time (Patent Documents 1 and 2).

However, in this procedures, the amount of inorganic filler in the resin composition is restricted for ensuring invasiveness of underfill and reliability of overmold, resulting in low flexibility for constitution of the resin. Therefore, it is difficult to perform overmolding and underfilling at the same time with reduced warp when a thin substrate with a large area is encapsulated. Thus, there is a problem that this procedure is insufficient to enhance the productivity in manufacturing a semiconductor apparatus.

Further, when the size of semiconductor devices of a flip chip semiconductor apparatus is large while the gap size is small, the transfer mold underfill and compression mold underfill are concerned about insufficient underfill.

### PRIOR ART REFERENCES

### Patent Documents

[Patent Document 1] Japanese Patent Application Publication No. 2012-74613

[Patent Document 2] Japanese Patent Application Publication No. 2011-132268

### SUMMARY OF THE INVENTION

The present invention has been accomplished in view of the above-mentioned circumstances, and an object thereof is to provide a method for manufacturing a semiconductor apparatus that can inhibit warping even when a thin substrate with a large area is encapsulated, sufficiently perform underfilling of semiconductor devices mounted by flip chip bonding, and manufacture a semiconductor apparatus excellent in encapsulating performance such as heat resistance and moisture resistance reliabilities without void and non-filling portion of the encapsulating layer.

To achieve the objects, the present invention provides a method for manufacturing a semiconductor apparatus, comprising an encapsulating step of collectively encapsulating a device mounting surface of a substrate having semiconductor devices mounted thereon with a base-attached encapsulant having a base and a thermosetting resin layer formed on one surface of the base, the semiconductor devices being mounted by flip chip bonding, the encapsulating step including:

a unifying stage of unifying the substrate having the semiconductor devices mounted thereon and the base-attached encapsulant under a reduced pressure condition with a vacuum of 10 kPa or less; and

a pressing stage of pressing the unified substrate with a pressure of 0.2 MPa or more.

Such a method for manufacturing a semiconductor apparatus can inhibit warping even when a thin substrate with a large area is encapsulated, sufficiently perform underfilling of semiconductor devices mounted by flip chip bonding, and manufacture a semiconductor apparatus excellent in encapsulating performance such as heat resistance and moisture resistance reliabilities without void and non-filling portion of the encapsulating layer.

The unifying stage is preferably carried out at a temperature of 80° C. to 200° C.

Such a unifying stage enables underfilling of semiconductor devices mounted by flip chip bonding to be excellently performed by the thermosetting resin layer of the base-attached encapsulant.

The pressing stage is preferably carried out at a temperature of 80° C. to 200° C.

Such a pressing stage enables substrate having semiconductor devices mounted thereon by flip chip bonding to be excellently encapsulated by the thermosetting resin layer of the base-attached encapsulant, whereby a semiconductor apparatus further excellent in encapsulating performance such as heat resistance and moisture resistance reliabilities can be obtained without void and non-filling portion of the encapsulating layer.

The inventive method for manufacturing a semiconductor apparatus may further comprise a piece forming step of dicing an encapsulated substrate having the semiconductor devices mounted thereon obtained by encapsulating the substrate having the semiconductor devices mounted thereon into individual pieces after the encapsulating step.

According to such a method for manufacturing a semiconductor apparatus, individual semiconductor apparatuses can be obtained by dicing the encapsulated substrate having the semiconductor devices mounted thereon.

In addition, the present invention provide a semiconductor apparatus manufactured by the above-mentioned method.

In the semiconductor apparatus obtained by the inventive method for manufacturing a semiconductor apparatus, warping is inhibited even when a thin substrate with a large area has been encapsulated, underfilling of semiconductor devices mounted by flip chip bonding is sufficiently performed, and excellent encapsulating performance such as heat resistance and moisture resistance reliabilities is provided without void and non-filling portion of the encapsulating layer.

As described above, the inventive method for manufacturing a semiconductor apparatus can inhibit warping even when a thin substrate with a large area is encapsulated since a shrinkage stress of the thermosetting resin layer can be suppressed by the base of the base-attached encapsulant at the time of curing and encapsulating. In addition, the unifying stage and the pressing stage enables sufficient underfilling of semiconductor devices mounted by flip chip bonding, and manufacturing of a semiconductor apparatus excellent in encapsulating performance such as heat resistance and moisture resistance reliabilities without void and non-filling portion of the encapsulating layer.

### BRIEF DESCRIPTION OF THE DRAWINGS

FIG. 1 is a flow diagram of an example of the inventive method for manufacturing a semiconductor apparatus;

FIG. 2 is a schematic cross-sectional view of an example of the inventive semiconductor apparatus; and

FIG. 3 is a chart showing temperature profile of an infrared (IR) reflow apparatus used in reflow resistance measurement.

### DETAILED DESCRIPTION OF THE PREFERRED EMBODIMENTS

As described above, it has been desired to develop a semiconductor apparatus in which warping is inhibited even when a thin substrate with a large area has been encapsulated, underfilling of semiconductor devices mounted by flip chip bonding is sufficiently performed, and excellent encapsulating performance such as heat resistance and moisture resistance reliabilities is provided without void and non-filling portion of the encapsulating layer.

The present inventors have diligently studied to accomplish the objects and consequently found that use of a base-attached encapsulant enables the warping to be inhibited since the shrinkage stress at the time of encapsulating is suppressed by the base even when a thin substrate with a large area is encapsulated, and that a method for manufacturing a semiconductor apparatus, including a unifying stage of unifying a substrate having semiconductor devices mounted thereon and the base-attached encapsulant under a reduced pressure condition with a vacuum of 10 kPa or less and a pressing stage of pressing the unified substrate with a pressure of 0.2 MPa or more, can provide a semiconductor apparatus with high reliability in which underfilling of the semiconductor devices mounted by flip chip bonding has been sufficiently performed without void, thereby bringing the present invention to completion.

Hereinafter, the present invention will be described in detail, but the present invention is not limited thereto.

### [Semiconductor Apparatus]

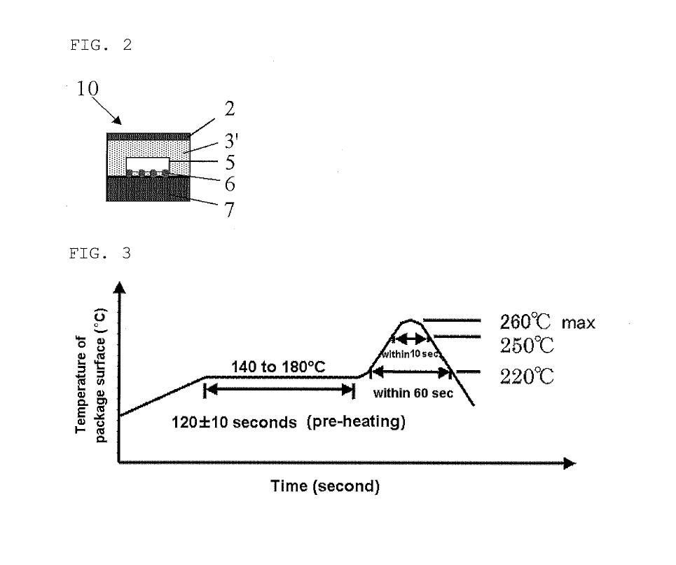

First, the inventive semiconductor apparatus manufactured by the inventive method for manufacturing a semiconductor apparatus is described. FIG. 2 is a schematic cross-sectional view of an example of the inventive semiconductor apparatus. In FIG. 2, a semiconductor apparatus 10 consists of a base 2, an encapsulating layer 3′ formed by heating and curing a thermosetting resin layer, semiconductor devices 5, bumps 6, and a substrate 7. The semiconductor devices 5 are mounted on the substrate 7 via a plurality of the bumps 6. The encapsulating layer 3′ for encapsulating the semiconductor devices 5 is formed between the base 2 and the substrate 7.

The inventive semiconductor apparatus is manufactured by the inventive method for manufacturing a semiconductor apparatus described in detail later. In this semiconductor apparatus, warping is inhibited even when a thin substrate with a large area has been encapsulated, underfilling of semiconductor devices mounted by flip chip bonding is sufficiently performed, and excellent encapsulating performance such as heat resistance and moisture resistance reliabilities is provided without void and non-filling portion of the encapsulating layer.

### [Method for Manufacturing a Semiconductor Apparatus]

Next, the inventive method for manufacturing a semiconductor apparatus is described. The inventive method for manufacturing a semiconductor apparatus involves an encapsulating step of collectively encapsulating a device mounting surface of a substrate having semiconductor devices mounted thereon (also referred to as a semiconductor device mounting substrate, hereinafter) by flip chip bonding with a base-attached encapsulant having a base and a thermosetting resin layer formed on one surface of the base, and the encapsulating step includes:

a unifying stage of unifying the substrate having semiconductor devices mounted thereon and the base-attached encapsulant under a reduced pressure condition with a vacuum of 10 kPa or less; and

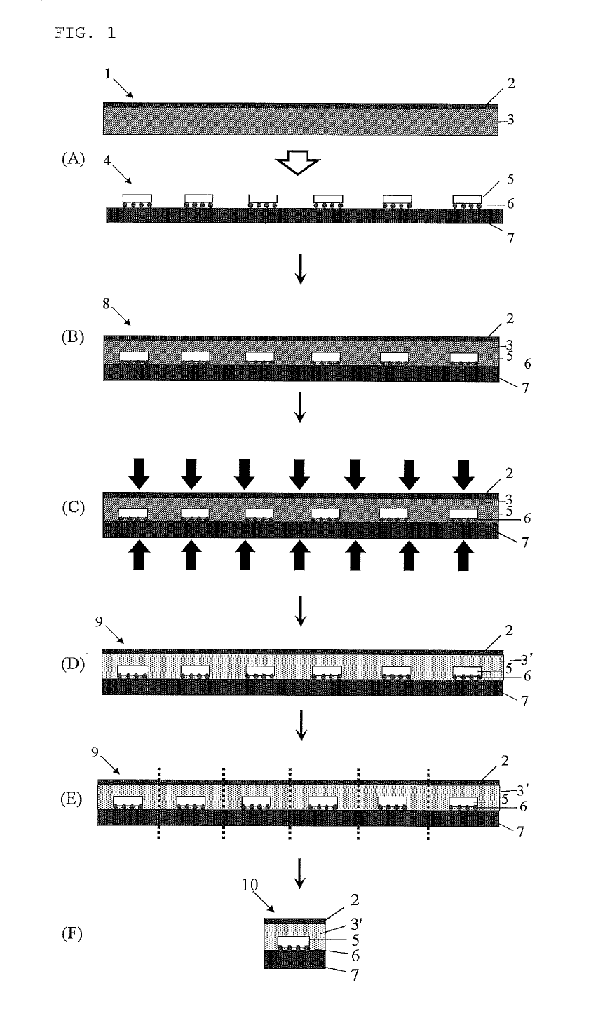

a pressing stage of pressing the unified substrate with a pressure of 0.2 MPa or more. A flow diagram of an example of the inventive method for manufacturing a semiconductor apparatus is shown in FIG. 1.

### [Base-Attached Encapsulant]

In the following, the base-attached encapsulant used in the inventive method for manufacturing a semiconductor apparatus is described. As shown in FIG. 1, the base-attached encapsulant 1 used in the inventive method for manufacturing a semiconductor apparatus consists of a base 2 and a thermosetting resin layer 3 formed on one surface of the base 2.

### <Base>

In the present invention, the base 2 of the base-attached encapsulant 1 is not particularly limited, and an inorganic substrate, a metal substrate, or an organic resin substrate may be used as the base 2 according to a subject to be encapsulated, a semiconductor device mounting substrate. In particular, when an organic resin substrate is used, the organic resin substrate may contain fiber.

Typical examples of the inorganic substrate include a ceramics substrate, a glass substrate, and a silicon wafer. Typical examples of the metal substrate include a copper or aluminum substrate whose surface has been subjected to an insulation treatment. Examples of the organic resin substrate include a resin-impregnated fiber base in which a thermosetting resin or a filler, etc., has been permeated into a fiber base, and a resin-impregnated fiber base in which the thermosetting resin has been semi-cured or cured, and a resin substrate in which a thermosetting resin has been formed into a substrate shape. Typical examples of the substrate include a BT (bismaleimide triazine) resin substrate, a glass epoxy substrate, and a FRP (fiber reinforced plastic) substrate.

Exemplary materials that can be used for the fiber base contained in the organic resin substrate include inorganic fibers such as carbon fiber, glass fiber, quartz glass fiber, and metal fiber; organic fibers such as aromatic polyamide fiber, polyimide fiber, and polyamideimide fiber; silicon carbide fiber; titanium carbide fiber; boron fiber; alumina fiber; and any other materials depending on the product properties. The most preferred fiber base may be exemplified by glass fiber, quartz fiber, or carbon fiber. Above all, glass fiber or quartz glass fiber having high insulation property is preferred as the fiber base.

The thermosetting resin used for the organic resin substrate is not particularly limited, but may be a BT resin or an epoxy resin; an epoxy resin, a silicone resin, a hybrid resin of an epoxy resin and a silicone resin, and a cyanate ester resin, which are conventionally used for encapsulating semiconductor devices and described below, may also be given as an example.

When the base-attached encapsulant used in the present invention is manufactured with a resin-impregnated fiber base using a thermosetting epoxy resin as the thermosetting resin to be permeated into the fiber base, or with the resin-impregnated fiber base in which the epoxy resin is semi-cured after permeating, the thermosetting resin used for forming the thermosetting resin layer on one surface of the base is also preferably an epoxy resin. When the thermosetting resin permeated into the base and the thermosetting resin used for forming the thermosetting resin layer on one surface of the base are identical, the resins can be simultaneously cured when a device mounting surface of the semiconductor device mounting substrate is collectively encapsulated, whereby more firm encapsulating function can be accomplished, so that it is preferable.

In all the cases of using an inorganic substrate, a metal substrate, or an organic resin substrate, the thickness of the base 2 is preferably in the range of 20 μm to 1 mm, more preferably 30 μm to 500 μm. The reason why such a thickness is preferable is that when the thickness is 20 μm or more, the substrate can be inhibited from becoming easy to deform due to being too thin; when the thickness is 1 mm or less, the semiconductor apparatus itself can be inhibited from becoming thick.

The base 2 is important to reduce the warp caused after a device mounting surface of the semiconductor device mounting substrate is collectively encapsulated and to reinforce a substrate in which one or more semiconductor devices are arranged and bonded. Accordingly, the base is preferably hard and robust.

### <Thermosetting Resin Layer>

The thermosetting resin layer 3 of the base-attached encapsulant used in the present invention is composed of an uncured or semi-cured thermosetting resin layer formed on one surface of the base 2. The thermosetting resin layer 3 is used as a resin layer for underfilling and overmolding of semiconductor devices mounted by flip chip bonding.

The thickness of the thermosetting resin layer 3 is preferably within a range of 20 μm to 2,000 μm. When the thickness is 20 μm or more, a semiconductor device mounting surface of various substrates on which semiconductor devices has been mounted is sufficiently encapsulated and the occurrence of a failure in filling due to being too thin can be inhibited; when the thickness is 2,000 μm or less, an encapsulated semiconductor apparatus can be inhibited from becoming too thick, so that it is preferable.

The resin used for the thermosetting resin layer 3 is preferably, but not limited to, a thermosetting resin of a liquid epoxy resin, a solid epoxy resin, a silicone resin, a hybrid resin of an epoxy resin and a silicone resin, or a cyanate ester resin, each of which is generally used for encapsulating semiconductor devices. In particular, the thermosetting resin layer preferably contains at least one of an epoxy resin, a silicone resin, an epoxy-silicone hybrid resin, and a cyanate ester resin, each of which solidifies at temperatures lower than 50° C. and melts at temperatures ranging from 50° C. to 150° C.

### <<Epoxy Resin>>

The epoxy resin that can be used for the thermosetting resin layer in the present invention may be for example, but not particularly limited to, a bisphenol A type epoxy resin, a bisphenol F type epoxy resin, a biphenol type epoxy resin such as a 3,3′,5,5′-tetramethyl-4,4′-biphenol type epoxy resin and a 4,4′-biphenol type epoxy resin, an epoxy resin in which an aromatic ring of a phenol novolac type epoxy resin, a cresol novolac type epoxy resin, a bisphenol A novolac type epoxy resin, a naphthalenediol type epoxy resin, a trisphenylolmethane type epoxy resin, a tetrakisphenylolethane type epoxy resin or a phenoldicyclopentadiene novolac type epoxy resin has been hydrogenated, and a conventionally known epoxy resin which is a liquid state or a solid state at room temperature such as an alicyclic epoxy resin, etc. An epoxy resin(s) other than the above may be used in combination with a certain amount depending on the purposes, if necessary.

In the thermosetting resin layer composed of an epoxy resin, a curing agent for an epoxy resin may be added. Examples of a usable curing agent include a phenol novolac resin, various kinds of amine derivatives, and an acid anhydride, and those in which an acid anhydride group is partially ring-opened to form a carboxylic acid. Above all, a phenol novolac resin is preferably used to ensure the reliability of a semiconductor apparatus to be manufactured by the method of present invention. It is particularly preferred that an epoxy resin and a phenol novolac resin are mixed such that the ratio of the epoxy group to the phenolic hydroxyl group becomes 1:0.8 to 1.3.

In addition, imidazole derivatives, phosphine derivatives, amine derivatives, a metal compound such as an organic aluminum compound, etc., may be used as a reaction promoter (catalyst) to promote the reaction of the epoxy resin and the curing agent.

The thermosetting resin layer composed of an epoxy resin may further contain various kinds of additives, if necessary. For example, for the purpose of improving the properties of the resin, various kinds of thermoplastic resins, thermoplastic elastomers, organic synthetic rubbers, stress lowering agents of silicone type or other type, waxes, and additives such as a halogen-trapping agent, etc., may be added properly depending on the purpose.

### <<Silicone Resin>>

The silicone resin that can be used for the thermosetting resin layer in the present invention may be, but not particularly limited to, a thermosetting silicone resin, a UV curable silicone resin, etc. In particular, the thermosetting resin layer composed of a silicone resin preferably contains an addition curable silicone resin composition. The addition curable silicone resin composition particularly preferred is a composition including (A) an organosilicon compound having a nonconjugated double bond (for example, an alkenyl group-containing diorganopolysiloxane), (B) an organohydrogen polysiloxane, and (C) a platinum type catalyst as essential components. These components of (A) to (C) will be described below.

### (A) Component: Organosilicon Compound Having Nonconjugated Double Bond

Examples of the organosilicon compound having a nonconjugated double bond, component (A), include an organopolysiloxane such as a linear diorganopolysiloxane in which both terminals of the molecular chain are blocked with triorganosiloxy groups containing aliphatic unsaturated groups as represented by:

R¹¹R¹²R¹³SiO—(R¹⁴R¹⁵SiO)ₐ—(R¹⁶R¹⁷SiO)_{b}—SiR¹¹R¹²R¹³ (1)

wherein R¹¹ represents a monovalent hydrocarbon group containing a nonconjugated double bond, R¹² to R¹⁷ each represent an identical or different monovalent hydrocarbon group, and “a” and “b” are each an integer satisfying 0≦a≦500, 0≦b≦250, and 0≦a+b≦500.

In the general formula (1), R¹¹ is a monovalent hydrocarbon group containing a nonconjugated double bond, and preferably a monovalent hydrocarbon group containing a nonconjugated double bond with an aliphatic unsaturated bond, as typified by an alkenyl group having 2 to 8 carbon atoms, particularly preferably 2 to 6 carbon atoms.

In the above general formula (1), R¹² to R¹⁷ each represent an identical or different monovalent hydrocarbon group; examples thereof include an alkyl group, an alkenyl group, an aryl group, and an aralkyl group each preferably having 1 to 20 carbon atoms, particularly preferably 1 to 10 carbon atoms. Among these, more preferable examples of R¹⁴ to R¹⁷ include a monovalent hydrocarbon group except for an aliphatic unsaturated bond; particularly preferable example thereof include an alkyl group, an aryl group, or aralkyl group, which do not have an aliphatic unsaturated bond unlike an alkenyl group. Among these, preferable examples of R¹⁶ and R¹⁷ include an aromatic monovalent hydrocarbon group; particularly preferable examples thereof include an aryl group having 6 to 12 carbon atoms such as a phenyl group and a tolyl group.

In the general formula (1), “a” and “b” are each preferably an integer satisfying 0≦a≦500, 0≦b≦250, and 0≦a+b≦500; “a” is more preferably 10≦a≦500; “b” is more preferably 0≦b≦150; and a+b more preferably satisfies 10≦a+b≦500.

The organopolysiloxane represented by the general formula (1) can be obtained, for example, by an alkali equilibration reaction between a cyclic diorganopolysiloxane such as cyclic diphenylpolysiloxane, or cyclic methylphenylpolysiloxane and a disiloxane such as diphenyltetravinyldisiloxane or divinyltetraphenyldisiloxane to constitute a terminal group. In this case, since, in an equilibration reaction by an alkali catalyst (particularly a strong alkali such as KOH), polymerization proceeds with a small amount of the catalyst by an irreversible reaction; thereby a ring-opening polymerization alone proceeds quantitatively and a terminal encapsulating ratio becomes high, a silanol group and a chlorine content are generally not contained.

The organopolysiloxane represented by the general formula (1) may be exemplified by the following,

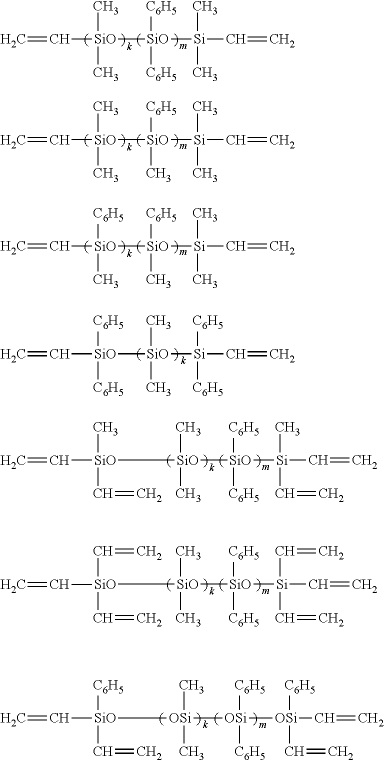

wherein “k” and “m” are each an integer satisfying 0≦k≦500, 0≦m≦250, and 0≦k+m≦500, preferably an integer satisfying 5≦k+m≦250 and 0≦m/(k+m)≦0.5.

The organopolysiloxane having a linear structure represented by the general formula (1) may be used as component (A) in combination with an organopolysiloxane having a three-dimensional network structure containing a tri-functional siloxane unit or a tetra-functional siloxane unit, etc., if needed. Such an organosilicon compound having a nonconjugated double bond may be used alone or in combination of two or more kinds.

The amount of the group having a nonconjugated double bond (a monovalent hydrocarbon group having a double bond and bonded to a Si atom, such as alkenyl group) in the organosilicon compound having a nonconjugated double bond, component (A), is preferably 0.1 to 20 mol % of the total amount of the monovalent hydrocarbon group (the total amount of a monovalent hydrocarbon group bonded to a Si atom), more preferably 0.2 to 10 mol %, particularly preferably 0.2 to 5 mol %. The reason why these amounts are preferable is that if the amount of the group having a nonconjugated double bond is 0.1 mol % or more, a good cured product can be obtained when it is cured, and if it is 20 mol % or less, the mechanical properties of a cured product become good.

In addition, the organosilicon compound having a nonconjugated double bond, component (A), preferably contains an aromatic monovalent hydrocarbon group (an aromatic monovalent hydrocarbon group bonded to a Si atom); the content of the aromatic monovalent hydrocarbon group is preferably 0 to 95 mol % of the total amount of the monovalent hydrocarbon group (the total amount of a monovalent hydrocarbon group bonded to a Si atom), more preferably 10 to 90 mol %, particularly preferably 20 to 80 mol %. When the aromatic monovalent hydrocarbon group is contained in the resin with a suitable amount, there are merits that mechanical properties when it is cured are good and producing thereof is easy.

### Component (B): Organohydrogenpolysiloxane

The component (B) is preferably an organohydrogenpolysiloxane having two or more hydrogen atoms bonded to silicon atoms (SiH groups) per molecule. The organohydrogenpolysiloxane having two or more hydrogen atoms bonded to silicon atoms (SiH groups) per molecule functions as a crosslinking agent and enables the formation of a cured product by addition reaction between the SiH group in component (B) and the group having a nonconjugated double bond, such as a vinyl group or other alkenyl groups, in component (A).

The organohydrogenpolysiloxane, component (B), preferably has an aromatic monovalent hydrocarbon group. If the organohydrogenpolysiloxane has an aromatic monovalent hydrocarbon group, compatibility with the component (A) can be increased. The organohydrogenpolysiloxane may be used alone or in combination of two or more kinds. For example, the organohydrogenpolysiloxane having an aromatic hydrocarbon group may be contained as a part of the component (B) or used as the component (B).

Examples of the organohydrogenpolysiloxane, component (B), include 1,1,3,3-tetramethyldisiloxane, 1,3,5,7-tetramethylcyclotetrasiloxane, tris(dimethylhydrogensiloxy)methylsilane, tris(dimethylhydrogensiloxy)phenylsilane, 1-glycidoxypropyl-1,3,5,7-tetramethylcyclotetrasiloxane, 1,5-glycidoxypropyl-1,3,5,7-tetramethylcyclotetrasiloxane, 1-glycidoxypropyl-5-trimethoxysilylethyl-1,3,5,7-tetramethylcyclotetrasiloxane, methylhydrogenpolysiloxane having both molecular terminals blocked with trimethylsiloxy groups, a dimethylsiloxane/methylhydrogensiloxane copolymer having both molecular terminals blocked with trimethylsiloxy groups, dimethylpolysiloxane having both molecular terminals blocked with dimethylhydrogensiloxy groups, a dimethylsiloxane/methylhydrogensiloxane copolymer having both molecular terminals blocked with dimethylhydrogensiloxy groups, a methylhydrogensiloxane/diphenylsiloxane copolymer having both molecular terminals blocked with trimethylsiloxy groups, a methylhydrogensiloxane/diphenylsiloxane/dimethylsiloxane copolymer having both molecular terminals blocked with trimethylsiloxy groups, a trimethoxysilane polymer, a copolymer of (CH₃)₂HSiO_{1/2} units and SiO_{4/2} units, and a copolymer of (CH₃)₂HSiO_{1/2} units, SiO_{4/2} units, and (C₆H₅)SiO_{3/2} units, but it is not limited thereto.

In addition, an organohydrogenpolysiloxane obtained by using units represented by the following structure may also be used.

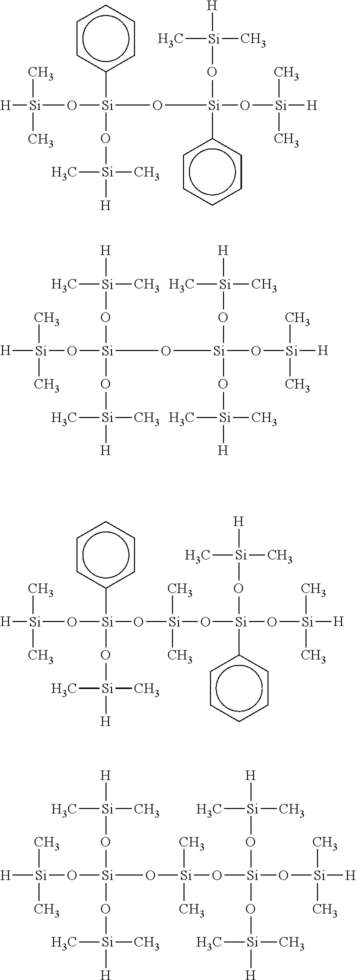

The molecular structure of the organohydrogenpolysiloxane, component (B), may be any of a linear, cyclic, branched, or three-dimensional network structure, and the number of silicon atoms per molecule (or a polymerization degree in case of a polymer) is preferably 2 or more, more preferably 3 to 500, particularly preferably 4 to 300 approximately.

The organohydrogenpolysiloxane, component (B), is preferably contained such that the number of hydrogen atoms bonded to silicon atoms (SiH groups) in component (B) is 0.7 to 3.0, particularly 1.0 to 2.0, per one group having a nonconjugated double bond, such as an alkenyl group, in component (A).

### Component (C): Platinum-Based Catalyst

Examples of the platinum-based catalyst, component (C), include a chloroplatinic acid, an alcohol-modified chloroplatinic acid, and a platinum complex having a chelate structure. These may be used alone or in combination of two or more kinds.

The formulation amount of the platinum-based catalyst, component (C), may be an effective amount for curing, or a so-called catalytic amount. A preferable amount thereof is generally 0.1 to 500 ppm in terms of a mass of the platinum group metal per a total amount of 100 mass parts of the component (A) and the component (B), and the range of 0.5 to 100 ppm is particularly preferable.

### <<Epoxy-Silicone Hybrid Resin>>

Examples of the epoxy-silicone hybrid resin used in the thermosetting resin layer in the present invention include, but are not particularly limited to, a hybrid resin using the above epoxy resin and the above silicone resin.

### <<Cyanate Ester Resin>>

The cyanate ester resin used for the thermosetting resin layer in the present invention may be, but not particularly limited to, a resin composition containing a cyanate ester compound or an oligomer thereof, and a phenol compound and/or a dihydroxynaphthalene compound as curing agent.

### (Cyanate Ester Compound or Oligomer Thereof)

The components used as the cyanate ester compound or the oligomer is represented by the following general formula (2),

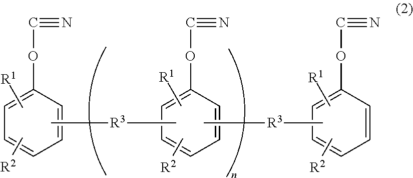

wherein R¹ and R² each represent a hydrogen atom or an alkyl group having 1 to 4 carbon atoms; R³ is represented by any one of:

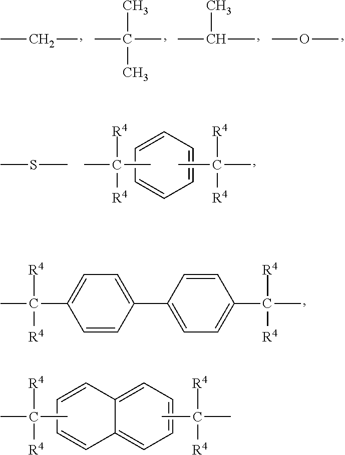

R⁴ represents a hydrogen atom or a methyl group; and “n” is an integer of 0 to 30.

The cyanate ester compound is a compound having two or more cyanate groups per molecule, and illustrative examples thereof include a cyanic acid ester of a polycyclic aromatic divalent phenol including, for example, bis(3,5-dimethyl-4-cyanatephenyl)methane, bis(4-cyanatephenyl)methane, bis(3-methyl-4-cyanatephenyl)methane, bis(3-ethyl-4-cyanatephenyl)methane, bis(4-cyanatephenyl)-1,1-ethane, bis(4-cyanatephenyl)-2,2-propane, di(4-cyanatephenyl) ether, di(4-cyanatephenyl)thioether; a polycyanic acid ester of a polyvalent phenol including, for example, a phenol novolac type cyanate ester, a cresol novolac type cyanate ester, a phenylaralkyl type cyanate ester, a biphenylaralkyl type cyanate ester, a naphthalenearalkyl type cyanate ester, etc.

The above cyanate ester compound can be obtained by reaction between a phenol and cyanogen chloride under basic conditions. The cyanate ester compound may be selected properly, depending on the use, from various materials with characteristics varied due to the structure themselves, such as a solid material having a softening point of 106° C. and a liquid material at room temperature.

Among them, a cyanate ester compound having a small cyanate equivalent, i.e., a small amount of molecular weight between functional groups exhibits a slight shrinkage due to curing, enabling a cured product having low thermal expansion and high glass transition temperature (Tg) to be obtained; a cyanate ester compound having a large cyanate equivalent exhibits slightly reduced Tg but increases the flexibility of a triazine cross-linking distance, enabling reduction in elasticity, increase in toughness and reduction in water absorbability to be expected.

Chlorine bonded to or remained in the cyanate ester compound is preferably 50 ppm or less, more preferably 20 ppm or less. If it is 50 ppm or less, there is slight possibility that chlorine or chlorine ions, liberated by thermal decomposition when being stored at a high temperature for a long period of time, corrode an oxidized Cu frame, Cu wire, or Ag plating, thereby causing exfoliation or electric failure, and insulation properties of resin becomes good.

### (Curing Agent)

As to the curing agent and curing catalyst of the cyanate ester compound, a metal salt, a metal complex, a phenolic hydroxyl group or a primary amine each having an active hydrogen, etc., are generally used, and a phenol compound or a dihydroxynaphthalene compound is particularly preferably used.

Examples of the phenol compound used in the cyanate ester resin include, but are not limited to, a compound represented by the following general formula (3),

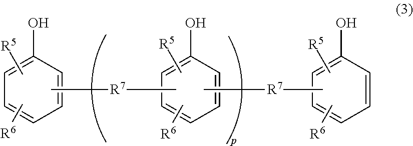

wherein R⁵ and R⁶ each represent a hydrogen atom or an alkyl group having 1 to 4 carbon atoms; R⁷ is represented by any one of:

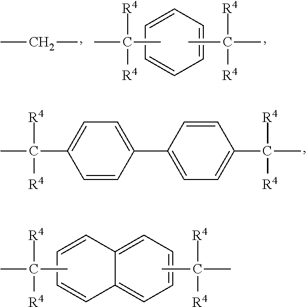

R⁴ represents a hydrogen atom or a methyl group; and “p” is an integer of 0 to 30.

Examples of the phenol compound include a phenol resin having two or more phenolic hydroxyl groups per molecule, a bisphenol F type resin, a bisphenol A type resin, a phenol novolac resin, a phenolaralkyl type resin, a biphenylaralkyl type resin, and a naphthalenearalkyl type resin; these may be used alone or in combination of two or more kinds.

Since a phenol compound having a small phenolic hydroxyl equivalent, for example, a hydroxyl equivalent of 120 or less, has high reactivity with a cyanate group, the curing reaction proceeds at a low temperature of 120° C. or lower. In this case, it is preferable to reduce the molar ratio of the hydroxyl group to the cyanate group. This ratio is preferably in the range of 0.05 mol to 0.11 mol per 1 mol of the cyanate group. In this case, a cured product exhibiting a slight shrinkage due to curing, a low thermal expansion, and high Tg can be obtained.

In contrast, since a phenol compound having a large phenolic hydroxyl equivalent, for example, a hydroxyl equivalent of 175 or more, has an inhibited reactivity with a cyanate group, a composition having good preservability and good flowability can be obtained. The ratio is preferably in the range of 0.1 mol to 0.4 mol per 1 mol of the cyanate group. In this case, a cured product having low water absorption but a slightly reduced Tg can be obtained. Such phenol resins may be used in combination of two or more kinds to obtain desired characteristics and curability of the cured product.

Dihydroxynaphthalene usable in the cyanate ester resin is represented by the following general formula (4).

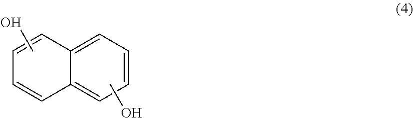

Examples of dihydroxynaphthalene include 1,2-dihydroxynaphthalene, 1,3-dihydroxynaphthalene, 1,4-dihydroxynaphthalene, 1,5-dihydroxynaphthalene, 1,6-dihydroxynaphthalene, 1,7-dihydroxynaphthalene, 2,6-dihydroxynaphthalene, 2,7-dihydroxynaphthalene. Among them, 1,2-dihydroxynaphthalene, 1,3-dihydroxynaphthalene, and 1,6-dihydroxynaphthalene each of which has a melting point of 130° C. have very high reactivity and promote cyclization reaction of the cyanate group with a small amount. 1,5-dihydroxynaphthalene and 2,6-dihydroxynaphthalene each of which has a melting point of 200° C. or higher relatively suppress the reaction.

Use of dihydroxynaphthalene alone makes the molecular weight between functional groups small and the structure rigid, enabling a cured product having a slight shrinkage due to curing and high Tg to be obtained. Use of dihydroxynaphthalene in combination with a phenol compound that has two or more hydroxyl groups in one molecule and hence has a large hydroxyl equivalent enables the curability to be adjusted.

A halogen element and an alkali metal in the above phenol compound and the dihydroxynaphthalene preferably exhibit 10 ppm or less, particularly preferably 5 ppm or less when the sample is extracted at 120° C. under 2 atm.

### <<Inorganic Filler>>

An inorganic filler may be blended in the thermosetting resin layer 3. Examples of the inorganic filler to be blended include silica such as fused silica and crystalline silica, alumina, silicon nitride, aluminum nitride, aluminosilicate, boron nitride, glass fiber, and antimonous trioxide.

In particular, when the thermosetting resin layer 3 is composed of an epoxy resin, a filler previously subjected to surface treatment with a coupling agent such as a silane coupling agent, a titanate coupling agent, etc., may be blended as the inorganic filler to increase bond strength of the epoxy resin and the inorganic filler.

Preferable examples of the coupling agent include epoxy functional alkoxysilanes such as γ-glycidoxypropyl-trimethoxysilane, γ-glycidoxypropylmethyldiethoxysilane, and β-(3,4-epoxycyclohexyl)ethyltrimethoxysilane; amino functional alkoxysilanes such as N-β-(aminoethyl)-γ-aminopropyltrimethoxysilane, γ-aminopropyltriethoxysilane, and N-phenyl-γ-aminopropyltrimethoxysilane; and mercapto functional alkoxysilanes such as γ-mercaptopropyl-trimethoxysilane. Incidentally, the formulation amount of the coupling agent to be used for the surface treatment and a method of the surface treatment are not particularly limited.

The average particle diameter of the inorganic filler is preferably 0.1 to 5 μm, more preferably 0.5 to 2 μm; and fillers with a particle diameter of half or more of a gap size between the substrate and the semiconductor devices mounted by flip chip bonding is preferably in an amount of 0.1% by mass or less of the whole inorganic filler.

If the average particle diameter is 0.1 μm or more, the thermosetting resin layer exhibits good viscosity, and if it is 5 μm or less, there is no fear that non-filling portion is generated due to clogging of the gap, so that it is preferable. In particular, it is preferred to use an inorganic filler with an average particle diameter of one tenth or less of the gap size and a maximum particle diameter of one third or less of the gap size.

If the fillers with a particle diameter of half or more of the gap size is in amount of 0.1% by mass or less of the whole inorganic filler, there is no fear that non-filling portion is generated. For example, in a semiconductor device mounting substrate with a narrow gap size of 20 μm, it is preferred to use an inorganic filler in which the ratio of a particle diameter of 10 μm or more is 0.1% by mass or less of the whole inorganic filler. If fillers having this particle diameter is in an amount of 0.1% by mass or less, non-filling portion and void are not generated due to clogging between bumps.

Here, as a method for measuring fillers having a particle diameter of half or more of the gap size, there may be used a particle diameter test method in which an inorganic filler and pure water are mixed with a (mass) ratio of 1:9, the agglomerates are disintegrated well by ultrasonic treatment and sieved thorough a filter having an opening half as large as the gap size, and the amount remaining on the filter is measured.

The amount of the inorganic filler is preferably 50 to 90% by mass, particularly preferably 60 to 85% by mass of the whole resin composition in the thermosetting resin layer of the base-attached encapsulant. If the amount is 50% by mass or more, reduction in strength, moisture resistance reliability, etc., can be inhibited. If the amount is 90% by mass or less, reduction in invasiveness of underfill due to thickening viscosity can be inhibited.

### <Method for Manufacturing a Base-Attached Encapsulant>

The base-attached encapsulant used in the present invention can be manufactured by forming a thermosetting resin layer on one surface of a base. The thermosetting resin layer can be formed by various methods such as a method of stacking an uncured or semi-cured thermosetting resin in a sheet state or a film state on a surface of the base and forming the resin layer by vacuum laminating, high-temperature vacuum pressing, or a heating roller, a method of applying a thermosetting resin, such as liquid epoxy resin or silicone resin, by printing or dispensing, etc., under a reduced pressure or a vacuum and then heating the resin, and a method of press-forming an uncured or semi-cured thermosetting resin.

The inventive method for manufacturing a semiconductor apparatus uses the base-attached encapsulant as mentioned above, thereby suppressing the shrinkage stress of the uncured or semi-cured resin layer at the time of curing and encapsulating. Therefore, warping can be inhibited when a thin substrate with a large area is encapsulated.

Hereinafter, the inventive method for manufacturing a semiconductor apparatus will be specifically described with reference to FIG. 1. The inventive method for manufacturing a semiconductor apparatus includes, for example, covering a device mounting surface of a semiconductor device mounting substrate 4, on which semiconductor devices mounted by flip chip bonding, with a thermosetting resin layer 3 of the base-attached encapsulant 1, then heating and curing the thermosetting resin layer 3 to collectively encapsulate the semiconductor device mounting surface (encapsulating step, (A) to (C)), and dicing into individual pieces the encapsulated semiconductor device mounting substrate 9 obtained by encapsulating the semiconductor device mounting substrate 4 (piece forming step, (D) to (F)) to manufacture a semiconductor apparatus 10. In the present invention, the encapsulating step includes a unifying stage ((A) to (B)) of unifying the semiconductor device mounting substrate 4 and the base-attached encapsulant 1 under a reduced pressure condition with a vacuum of 10 kPa or less and a pressing stage (C) of pressing the unified substrate 8 with a pressure of 0.2 MPa or more. Hereinafter, each stage is described, but the present invention is not limited thereto.

### [Encapsulating Step]

FIG. 1 shows a semiconductor device mounting substrate 4, in which semiconductor devices 5 are mounted on a substrate 7 via bumps 6. In FIG. 1, a device mounting surface of the semiconductor device mounting substrate 4 is covered with a thermosetting resin layer 3 of a base-attached encapsulant 1, and collectively encapsulated ((A) to (C)). Examples of the base-attached encapsulant used at this time are as exemplified above.

### [Unifying Stage]

The encapsulating step of the inventive method for manufacturing a semiconductor apparatus includes a unifying stage of unifying the semiconductor device mounting substrate 4 and the base-attached encapsulant 1 under a reduced pressure with a vacuum of 10 kPa or less ((A) to (B)). In the unifying stage, underfilling of the semiconductor devices 5 is performed.

When the semiconductor device mounting substrate and the base-attached encapsulant are unified under a reduced pressure with a vacuum of 10 kPa or less, underfilling of the semiconductor devices is excellently performed by the thermosetting resin layer of the base-attached encapsulant without generation of non-filling portion, and thus void does not occur at the unifying stage. If the vacuum exceeds 10 kPa, underfilling is not performed well and non-filling portion is generated. Thus, voids are likely to occur, which causes reduction in reliability.

The unifying stage is preferably performed at a temperature of 80° C. to 200° C., more preferably at a temperature of 120° C. to 180° C. When the unifying stage is performed at a temperature of 80° C. to 200° C., underfilling of semiconductor devices is excellently performed. If the temperature is 80° C. or higher, the thermosetting resin layer is sufficiently melted and good flowability is obtained, therefore underfilling can be more excellently performed. If the temperature is 200° C. or lower, curing rate of the thermosetting resin layer does not become too fast and flowability of the resin is not lost even when semiconductor devices with large area are underfilled, therefore underfilling can be performed without generation of non-filling portion.

Examples of an apparatus for performing the unifying stage include a vacuum laminator apparatus for use in lamination of a solder resist film, various kinds of insulator films, and others. As a lamination method, any methods can be applied, such as roll lamination, diaphragm type vacuum lamination, air-pressure lamination, and others.

Further, in the unifying stage, the atmosphere may be restored from reduced state to atmospheric pressure before a subsequent pressing stage. By restoring from reduced pressure to atmospheric pressure, more excellent underfilling property can be obtained.

### [Pressing Stage]

Then, the pressing stage is described. The encapsulating step of the inventive method for manufacturing a semiconductor apparatus includes a pressing stage of pressing the substrate unified in the unifying step (unified substrate 8) with a pressure of 0.2 MPa or more (C). In the pressing stage, overmolding of the unified substrate 8, which has been subjected to underfilling in the unifying step, is performed.

When the unified substrate is pressed with a pressure of 0.2 MPa or more, overmolding is excellently performed by the thermosetting resin layer of the base-attached encapsulant. If the pressure is less than 0.2 MPa, void occurs due to volatile components of the thermosetting resin layer, which causes reduction in reliability.

The pressing stage is preferably performed at a temperature of 80° C. to 200° C., more preferably at a temperature of 120° C. to 180° C. If the temperature is 80° C. or higher, the thermosetting resin layer is sufficiently melted and good flowability is obtained, therefore non-filling portion of the encapsulating layer is not generated. In addition, since curing does not take time, semiconductor apparatuses can be manufactured with good productivity. If the temperature is 200° C. or lower, curing rate of the resin does not become too fast and good flowability can be obtained, therefore non-filling portion of the encapsulating layer is not generated.

An apparatus for performing the pressing stage may be a conventionally known pressing apparatus. For example, a compression molding apparatus can be used.

Further, the pressing stage may be performed under low pressure atmosphere. By performing under low pressure atmosphere, generation of defects such as void and non-filling portion can be further prevented.

When the pressing stage is performed under low pressure atmosphere, the pressing stage can be successively or simultaneously performed with the unifying stage by the same apparatus.

As an apparatus for performing the pressing stage under low pressure atmosphere, a vacuum compression molding apparatus, a vacuum laminating apparatus, etc., can be used. Above all, it is preferred to use both vacuum lamination and air-pressure method.

### [Piece Forming Step]

The inventive method for manufacturing a semiconductor apparatus may further include a piece forming step of dicing an encapsulated semiconductor device mounting substrate obtained by encapsulating the semiconductor device mounting substrate into individual pieces after the encapsulating step ((D) to (F)).

The encapsulated semiconductor device mounting substrate 9 is obtained by performing the underfilling of the semiconductor devices 5 by the thermosetting resin layer 3 of the base-attached encapsulant 1, heating and curing the thermosetting resin layer 3 into the encapsulating layer 3′ to collectively encapsulate the semiconductor device mounting substrate 4. In the piece forming step, the encapsulated semiconductor device mounting substrate 9 is diced into individual pieces to obtain a semiconductor apparatus 10.

As described above, the inventive method for manufacturing a semiconductor apparatus can inhibit warping even when a thin substrate with a large area is encapsulated since a shrinkage stress of the uncured or semi-cured resin layer can be suppressed by the base of the base-attached encapsulant at the time of curing and encapsulating, sufficiently perform underfilling of semiconductor devices mounted by flip chip bonding, and manufacture a semiconductor apparatus excellent in encapsulating performance such as heat resistance and moisture resistance reliabilities without void and non-filling portion of the encapsulating layer.

### EXAMPLES

Hereinafter, the present invention will be described in detail with reference to Examples and Comparative Examples, but the present invention is not restricted thereto.

### Example 1

### Preparation of Base

A BT (bismaleimide triazine) resin substrate (glass transition temperature: 185° C.) having a thickness of 50 μm and a size of 66 mm×232 mm was prepared as a base.

### [Manufacture of Resin Composition of Thermosetting Resin Layer]

60 parts by mass of a cresol novolac type epoxy resin, 30 parts by mass of a phenol novolac resin, 400 parts by mass of spherical silica having an average particle diameter of 1.2 μm, 0.2 part by mass of a catalyst TPP (triphenylphosphine), 0.5 part by mass of a silane coupling agent (KBM403 available from Shin-Etsu Chemical Co., Ltd.), and 3 parts by mass of a black pigment were sufficiently mixed by a high-speed mixing apparatus, and kneaded under heating by a continuous kneading apparatus to make a sheet and the sheet was then cooled. The sheet was crushed to obtain an epoxy resin composition as granular powder.

### [Manufacture of Base-Attached Encapsulant]

The granular powder of the epoxy resin composition was uniformly dispersed on one surface of the base. The temperatures of the upper and lower molds were set at 80° C., a PET film (a peeling film) coated with a fluorine resin was set to the upper mold, and the pressure inside the mold was reduced to a vacuum level and compression molding was carried out for 3 minutes such that thickness of the resin is 200 μm to form a thermosetting resin layer. Thus, a base-attached encapsulant was manufactured.

### [Semiconductor Device Mounting Substrate]

A substrate in which 64 Si chips each having a thickness of 100 μm and a size of 10×10 mm had been mounted on a BT substrate having a thickness of 100 μm and a size of 74×240 mm so as to give a gap size of about 30 μm was prepared.

### [Manufacture of Semiconductor Apparatus]

The base-attached encapsulant and the semiconductor device mounting substrate were unified by a vacuum laminating apparatus (manufactured by Nichigo-Morton Co., Ltd.) under conditions with a vacuum of 50 Pa at a temperature of 150° C. The unified substrate was cured and encapsulated by pressing for 3 minutes with a pressure of 5 MPa at 175° C. by a compression molding apparatus. After curing and encapsulating, post-cure was performed at 180° C. for 4 hours to obtain a semiconductor apparatus.

### Example 2

A base-attached encapsulant and a semiconductor device mounting substrate were prepared in the same manner as in Example 1.

### [Manufacture of Semiconductor Apparatus]

The base-attached encapsulant and the semiconductor device mounting substrate were unified by a vacuum laminating apparatus (manufactured by Nichigo-Morton Co., Ltd.) under conditions with a vacuum of 100 Pa at a temperature of 150° C. The unified substrate was cured and encapsulated by pressing for 3 minutes with a pressure of 5 MPa at 175° C. by a compression molding apparatus. After curing and encapsulating, post-cure was performed at 180° C. for 4 hours to obtain a semiconductor apparatus.

### Example 3

A base-attached encapsulant and a semiconductor device mounting substrate were prepared in the same manner as in Example 1.

### [Manufacture of Semiconductor Apparatus]

The base-attached encapsulant and the semiconductor device mounting substrate were unified by a vacuum laminating apparatus (manufactured by Nichigo-Morton Co., Ltd.) under conditions with a vacuum of 100 Pa at a temperature of 150° C. The unified substrate was cured and encapsulated by pressing for 3 minutes with a pressure of 3 MPa at 175° C. by a compression molding apparatus. After curing and encapsulating, post-cure was performed at 180° C. for 4 hours to obtain a semiconductor apparatus.

### Example 4

A base-attached encapsulant and a semiconductor device mounting substrate were prepared in the same manner as in Example 1.

### [Manufacture of Semiconductor Apparatus]

The base-attached encapsulant and the semiconductor device mounting substrate were unified by a vacuum laminating apparatus (manufactured by Nichigo-Morton Co., Ltd.) under conditions with a vacuum of 50 Pa at a temperature of 150° C. The unified substrate was cured and encapsulated by pressing for 3 minutes with a pressure of 1 MPa at 175° C. by a compression molding apparatus. After curing and encapsulating, post-cure was performed at 180° C. for 4 hours to obtain a semiconductor apparatus.

### Example 5

A base-attached encapsulant was prepared in the same manner as in Example 1.

### [Semiconductor Device Mounting Substrate]

A substrate in which 30 Si chips each having a thickness of 100 μm and a size of 20×20 mm had been mounted on a BT substrate having a thickness of 100 μm and a size of 74×240 mm so as to give a gap size of about 30 μm was prepared.

### [Manufacture of Semiconductor Apparatus]

A semiconductor apparatus was obtained in the same manner as in Example 1.

### Example 6

A base-attached encapsulant was prepared in the same manner as in Example 1.

### [Semiconductor Device Mounting Substrate]

A substrate in which 30 Si chips each having a thickness of 100 μm and a size of 20×20 mm had been mounted on a BT substrate having a thickness of 100 μm and a size of 74×240 mm so as to give a gap size of about 20 μm was prepared.

### [Manufacture of Semiconductor Apparatus]

A semiconductor apparatus was obtained in the same manner as in Example 1.

### Example 7

A base-attached encapsulant and a semiconductor device mounting substrate were prepared in the same manner as in Example 1.

### [Manufacture of Semiconductor Apparatus]

The base-attached encapsulant and the semiconductor device mounting substrate were unified by a vacuum laminating apparatus (manufactured by Nichigo-Morton Co., Ltd.) under conditions with a vacuum of 100 Pa at a temperature of 150° C., and successively, cured and encapsulated by pressing for 3 minutes with a pressure of 5 MPa under the same condition by the same apparatus. After curing and encapsulating, post-cure was performed at 180° C. for 4 hours to obtain a semiconductor apparatus.

### Comparative Example 1

A resin composition of a thermosetting resin layer and a semiconductor device mounting substrate were prepared in the same manner as in Example 1.

### [Manufacture of Semiconductor Apparatus]

The granular powder of the resin composition was placed on a semiconductor device mounting surface of the semiconductor device mounting substrate, and unified by a vacuum laminating apparatus (manufactured by Nichigo-Morton Co., Ltd.) under conditions with a vacuum of 50 Pa at a temperature of 150° C. The unified substrate was cured and encapsulated by pressing for 3 minutes with a pressure of 5 MPa at 175° C. by a compression molding apparatus. After curing and encapsulating, post-cure was performed at 180° C. for 4 hours to obtain a semiconductor apparatus.

### Comparative Example 2

A base-attached encapsulant and a semiconductor device mounting substrate were prepared in the same manner as in Example 1.

### [Manufacture of Semiconductor Apparatus]

The base-attached encapsulant and the semiconductor device mounting substrate were unified by a vacuum laminating apparatus (manufactured by Nichigo-Morton Co., Ltd.) at 150° C. without reducing pressure. The unified substrate was cured and encapsulated by pressing for 3 minutes with a pressure of 5 MPa at 175° C. by a compression molding apparatus. After curing and encapsulating, post-cure was performed at 180° C. for 4 hours to obtain a semiconductor apparatus.

### Comparative Example 3

A base-attached encapsulant and a semiconductor device mounting substrate were prepared in the same manner as in Example 1.

### [Manufacture of Semiconductor Apparatus]

The base-attached encapsulant and the semiconductor device mounting substrate were unified by a vacuum laminating apparatus (manufactured by Nichigo-Morton Co., Ltd.) under conditions with a vacuum of 20 kPa at a temperature of 150° C. The unified substrate was cured and encapsulated by pressing for 3 minutes with a pressure of 5 MPa at 175° C. by a compression molding apparatus. After curing and encapsulating, post-cure was performed at 180° C. for 4 hours to obtain a semiconductor apparatus.

### Comparative Example 4

A base-attached encapsulant and a semiconductor device mounting substrate were prepared in the same manner as in Example 1.

### [Manufacture of Semiconductor Apparatus]

The base-attached encapsulant and the semiconductor device mounting substrate were unified by a vacuum laminating apparatus (manufactured by Nichigo-Morton Co., Ltd.) under conditions with a vacuum of 20 kPa at a temperature of 150° C. The unified substrate was cured and encapsulated by heating for 3 minutes at 175° C. without pressing. After curing and encapsulating, post-cure was performed at 180° C. for 4 hours to obtain a semiconductor apparatus.

### Comparative Example 5

A base-attached encapsulant and a semiconductor device mounting substrate were prepared in the same manner as in Example 1.

### [Manufacture of Semiconductor Apparatus]

The base-attached encapsulant and the semiconductor device mounting substrate were unified by a vacuum laminating apparatus (manufactured by Nichigo-Morton Co., Ltd.) under conditions with a vacuum of 50 Pa at a temperature of 150° C. The unified substrate was cured and encapsulated by pressing for 3 minutes with a pressure of 0.15 MPa at 175° C. by a compression molding apparatus. After curing and encapsulating, post-cure was performed at 180° C. for 4 hours to obtain a semiconductor apparatus.

Properties of the semiconductor apparatuses obtained in Examples 1 to 7 and Comparative Example 1 to 5 were evaluated. The evaluation results are shown in Tables 1 and 2.

### <Warp of Package>

The difference in height of the semiconductor apparatus was measured in a diagonal direction with a laser coordinate measuring machine to define the difference as the amount of warp.

### <Invasiveness of Underfill>

The semiconductor apparatus was investigated by an ultrasonic testing apparatus and observation of the cross-section of a cut semiconductor device of the semiconductor apparatus to check voids and a portion which does not filled with the resin (a non-filling portion) in the underfill part. When there was no void and no non-filling portion, the invasiveness was determined as good.

### <Filling Performance of Encapsulating Layer>

The semiconductor apparatus was investigated by an ultrasonic testing apparatus and observation of the cross-section of a cut semiconductor apparatus to check voids and a non-filling portion in the encapsulating layer. When there was no void and no non-filling portion, it was determined as good.

### <Solder Reflow Resistance>

The semiconductor apparatuses obtained in Examples and Conductive Examples were each diced into individual pieces, and left in a thermo-hygrostat at 85° C. and 60% RH for 168 hours to absorb moisture. Then, IR reflow condition shown in FIG. 3 was applied 3 times by using an IR reflow apparatus to conduct an IR reflow process (based on JEDEC Level 2 at 260° C.). The occurrence of an internal crack and peeling were observed by an ultrasonic testing apparatus and observation of the cross-section of a cut semiconductor device. The number of packages containing a crack or peeling was counted among a total of 20 packages.

TABLE 1

| | Example 1 | Example 2 | Example 3 | Example 4 | Example 5 | Example 6 | Example 7 |
|---|---|---|---|---|---|---|---|
| Warp of | 0.05 | 0.05 | 0.06 | 0.05 | 0.08 | 0.11 | 0.05 |
| package (mm) | | | | | | | |
| Underfill | good | good | good | good | good | good | good |
| invasiveness | | | | | | | |
| Encapsulating | good | good | good | good | good | good | good |
| layer filling | | | | | | | |
| performance | | | | | | | |
| Number of | 0/20 | 0/20 | 0/20 | 0/20 | 0/20 | 0/20 | 0/20 |
| package | | | | | | | |
| containing | | | | | | | |
| crack or | | | | | | | |
| peeling after | | | | | | | |
| IR reflow | | | | | | | |
| process | | | | | | | |

TABLE 2

| | Compar- | Compar- | Compar- | Compar- | Compar- |
|---|---|---|---|---|---|
| | ative | ative | ative | ative | ative |
| | Example 1 | Example 2 | Example 3 | Example 4 | Example 5 |
| Warp of | 8 | 0.06 | 0.05 | 0.05 | 0.06 |
| package | | | | | |
| (mm) | | | | | |
| Underfill | good | non-filling | non-filling | void | void |
| invasiveness | | portion | portion | | |
| Encap- | good | good | good | void | void |
| sulating | | | | | |
| layer filling | | | | | |
| performance | | | | | |
| Number of | 5/20 | — | — | — | — |
| package | | | | | |
| containing | | | | | |
| crack or | | | | | |
| peeling after | | | | | |
| IR reflow | | | | | |
| process | | | | | |

As shown in Tables 1 and 2, in the semiconductor apparatus obtained by the inventive method for manufacturing a semiconductor apparatus, the warp of the substrate was markedly inhibited, voids and non-filling portion were not found in the encapsulating layer and the underfill portion of semiconductor devices mounted by flip chip bonding, and crack and peeling after the IR reflow process hardly occurred.

On the other hand, in Comparative Example 1 using no base-attached encapsulant, the warp was not inhibited and crack and peeling after the IR reflow process were often found. Comparative Example 2, in which the pressure was not reduced in the unifying stage, and Comparative Example 3, in which a degree of vacuum exceeded 10 kPa, showed failure in invasiveness of underfill although the warp of package was small and the filling performance of the encapsulating layer was good. Comparative Example 4, in which a degree of vacuum exceeded 10 kPa and the unified substrate was not pressed, and Comparative Example 5, in which the substrate was pressed with a pressure of 0.2 MPa below in the pressing stage, showed failure in invasiveness of underfill and filling of the encapsulating layer, such as voids and non-filling portion, although the warp of the package was small.

From these results, it was revealed that the inventive method for manufacturing a semiconductor apparatus can inhibit warping even when a thin substrate with a large area is encapsulated, sufficiently perform underfilling of semiconductor devices mounted by flip chip bonding, and provide a semiconductor apparatus excellent in encapsulating performance such as heat resistance and moisture resistance reliabilities without void and non-filling portion of the encapsulating layer.

It is to be noted that the present invention is not restricted to the foregoing embodiment. The embodiment is just an exemplification, and any examples that have substantially the same feature and demonstrate the same functions and effects as those in the technical concept described in claims of the present invention are included in the technical scope of the present invention.

What is claimed is:

1. A method for manufacturing a semiconductor apparatus, comprising an encapsulating step of collectively encapsulating a device mounting surface of a substrate having semiconductor devices mounted thereon with a base-attached encapsulant having a base and a thermosetting resin layer formed on one surface of the base, the semiconductor devices being mounted by flip chip bonding, the encapsulating step including:
a unifying stage of unifying the substrate having the semiconductor devices mounted thereon and the base-attached encapsulant under a reduced pressure condition with a vacuum of 10 kPa or less; and
a pressing stage of pressing the unified substrate with a pressure of 0.2 MPa or more.

2. The method for manufacturing a semiconductor apparatus according to claim 1, wherein the unifying stage is carried out at a temperature of 80° C. to 200° C.

3. The method for manufacturing a semiconductor apparatus according to claim 1, wherein the pressing stage is carried out at a temperature of 80° C. to 200° C.

4. The method for manufacturing a semiconductor apparatus according to claim 2, wherein the pressing stage is carried out at a temperature of 80° C. to 200° C.

5. The method for manufacturing a semiconductor apparatus according to claim 1, further comprising a piece forming step of dicing an encapsulated substrate having the semiconductor devices mounted thereon obtained by encapsulating the substrate having the semiconductor devices mounted thereon into individual pieces after the encapsulating step.

6. The method for manufacturing a semiconductor apparatus according to claim 2, further comprising a piece forming step of dicing an encapsulated substrate having the semiconductor devices mounted thereon obtained by encapsulating the substrate having the semiconductor devices mounted thereon into individual pieces after the encapsulating step.

7. The method for manufacturing a semiconductor apparatus according to claim 3, further comprising a piece forming step of dicing an encapsulated substrate having the semiconductor devices mounted thereon obtained by encapsulating the substrate having the semiconductor devices mounted thereon into individual pieces after the encapsulating step.

8. The method for manufacturing a semiconductor apparatus according to claim 4, further comprising a piece forming step of dicing an encapsulated substrate having the semiconductor devices mounted thereon obtained by encapsulating the substrate having the semiconductor devices mounted thereon into individual pieces after the encapsulating step.

9. A semiconductor apparatus manufactured by the method according to claim 1.

10. A semiconductor apparatus manufactured by the method according to claim 2.

11. A semiconductor apparatus manufactured by the method according to claim 3.

12. A semiconductor apparatus manufactured by the method according to claim 4.

13. A semiconductor apparatus manufactured by the method according to claim 5.

14. A semiconductor apparatus manufactured by the method according to claim 6.

15. A semiconductor apparatus manufactured by the method according to claim 7.

16. A semiconductor apparatus manufactured by the method according to claim 8.
